(19) United States
(12) Patent Application Publication
(10) Pub. No.: US 2016/0289813 A1
(43) Pub. Date: Oct. 6, 2016

(54) METHOD FOR MANUFACURING AMORPHOUS ALLOY FILM AND METHOD FOR MANUFACTURING NANOSTRUCTURED FILM COMPRISING NITORGEN

(71) Applicant: KOREA INSTITUTE OF INDUSTRIAL TECHNOLOGY, Chungcheongnam-do (KR)

(72) Inventors: Seungyong SHIN, Seoul (KR); Kyoungil MOON, Incheon (KR); Juhyun Sun, Incheon (KR); Changhun LEE, Incheon (KR)

(21) Appl. No.: 14/787,132

(22) PCT Filed: Apr. 25, 2014
(86) PCT No.: PCT/KR2014/003651

§ 371 Date: Oct. 26, 2015

(30) Foreign Application Priority Data
Apr. 26, 2013 (KR) 10-2013-0046627

(51) Int. Cl. C23C 14/00; C23C 14/14; H01J 37/34; C22C 16/00; B82Y 30/00; C22F 1/18; B22F 9/08; B22D 18/00; B22D 13/06; C23C 14/34; C22C 1/00

(52) U.S. Cl. CPC C23C 14/0036; C23C 14/34; C23C 14/14; C23C 14/3414; H01J 37/3429; C22C 16/00; C22C 1/002; C22F 1/186; B22F 9/082; B22D 18/00; B22D 13/06; B82Y 30/00; B22F 2009/0848

(57) ABSTRACT

The purpose of the present invention is to provide a nanostructured composite thin film showing low friction properties and a method for manufacturing same, and a member with low friction properties and a method for manufacturing same, wherein the thin film shows an exceptionally low value of friction coefficient but also shows high hardness and adhesion in comparison with conventional thin films, and the member has such a nanostructured composite thin film formed on the surface thereof. Provided, according to one aspect of the present invention, is a nanostructured composite thin film having low friction properties which has a composite structure in which a nitride phase comprising Zr and Al as a nitride component and at least one metallic phase are mixed, and has the size of a crystal grain in the range of 5 nm to 30 nm. Here, the nitride phase has a crystal structure of Zr nitride, and the metallic phase can comprise one or more selected from Cu and Ni.

### TECHNICAL FIELD

The present invention is related to a thin film. In particular, the present invention is related to a method for manufacturing an amorphous alloy film and a nanostructured film.

### BACKGROUND ART

Superior lubricative properties is usually required for operating parts in various machine apparatus, slide members, or various tools. In order to improve the lubricative properties, a technology in which a thin film with low friction properties is formed on surfaces of matrix can be applied. For example, energy will be lost due to the friction between various parts during operation of an engine of a vehicle. When the friction between the operation parts is reduced, the fuel loss of the vehicle is decreased, thereby increasing fuel efficiency. Since the thin film with low friction properties should be endured under severe frictional environment, the thin film should have hardness over a predetermined level, an adhesive force to a matrix, and high resistance against oxidizing atmosphere. Such a thin film with the low friction properties includes ceramic material such as nitride materials or carbonate having high hardness, or DLC (diamond like carbon). The thin film can be applied to the matrix by a physical deposition method, a chemical deposition method, plasma spraying coating method, or the like.

Although a conventional ceramic thin film has high hardness above about 2000 Hv, is has a significant difference in modulus of elasticity from the metal material such as steel, aluminum, magnesium, or the like used for the matrix. For example, the modulus of elasticity of the most high melting point ceramic materials is in the range of 400 GPa through 700 GPa. However, the modulus of elasticity of aluminum alloy is about 70 GPa, the modulus of elasticity of magnesium alloy is about 45 GPa, and the modulus of elasticity of steel is about 200 GPa. Thus, the difference in the elasticity of aluminum between the ceramic thin film and the metal material is significantly great so as to generate duration problems. In addition, a friction coefficient of the ceramic thin film has too high to apply to important driving components such as a vehicle engine. In the DLC film, the effect of reducing friction is not significant under boundary lubricative environment. Since the DLC is a meta stable phase, the graphitization (sp³->sp²) is proceeded due to the abrasion under boundary lubricative environment with temperature increase by contact between solid phases of a fraction portions, thereby generating the significant abrasion in the layer. The layer is not suitable to additive material, such as a friction modifier added into the lubricative oil, for example Molybdenum dialkyldithiocarbamate (MoDTC), thereby decreasing the effects of the addictive material and promoting abrasion of the DLC layer.

### DETAILED DESCRIPTION OF THE INVENTION

### Technical Problem

The purpose of the present invention is to provide a nanostructured composite thin film showing low friction properties and a method for manufacturing same, and a member with low friction properties and a method for manufacturing same, wherein the thin film shows an exceptionally low value of friction coefficient but also shows high hardness and adhesion in comparison with conventional thin films, and the member has such a nanostructured composite thin film formed on the surface thereof. However, this purpose is exemplary, and the present invention is not limited thereto.

### Technical Solution

A method of manufacturing a nanostructured film having nitrogen according to one aspect of the present invention is provided. The method of manufacturing a nanostructured film comprising nitrogen includes: forming a nanostructured film having nitrogen on a substrate by sputtering an alloy target with injection of a reactive gas having nitrogen or nitrogen gas (N2) or nitrogen (N) into a sputtering apparatus, wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy, wherein the alloy target has a microstructure in which crystal grains having an average size in the range of 0.1 μm through 5 μm are uniformly distributed, wherein the amorphous alloy or nano-crystalline alloy has 5 through 20 atomic % of Al, 15 through 40 atomic % of one or more selected from Cu and Ni, and a balance of Zr.

A method of manufacturing a nanostructured film having nitrogen according to another aspect of the present invention is provided. The method of manufacturing a nanostructured film comprising nitrogen includes: forming a nanostructured film having nitrogen on a substrate by sputtering an alloy target with injection of a reactive gas having nitrogen or nitrogen gas (N2) or nitrogen (N) into a sputtering apparatus, wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy, wherein the alloy target has a microstructure in which crystal grains having an average size in the range of 0.1 μm through 5 μm are uniformly distributed, wherein the amorphous alloy or nano-crystalline alloy has 5 through 20 atomic % of Al, 15 through 40 atomic % of one or more selected from Cu and Ni, more than 0 through 8 atomic % of one or more selected from Cr, Mo, Si, Nb, Co, Sn, In, Bi, Zn, V, Hf, Ag, Ti, and Fe, and a balance of Zr.

The method of manufacturing a nanostructured film comprising nitrogen may include forming a buffer layer on the substrate before forming the nanostructured film.

In the method of manufacturing the nanostructured film comprising nitrogen, the buffer layer may include an amorphous alloy thin film or a Ti layer.

In the method of manufacturing the nanostructured film comprising nitrogen, the buffer layer may have a dual layer structure in which a Ti layer and an amorphous alloy thin film are sequentially stacked on a matrix

In the method of manufacturing the nanostructured film comprising nitrogen, an interface of the buffer layer and the nanostructured film may have a boundary layer having a composition gradient of nitrogen or elements forming the buffer layer.

In the method of manufacturing the nanostructured film comprising nitrogen, the amorphous alloy thin film may be formed by sputtering the alloy target.

In the method of manufacturing the nanostructured film comprising nitrogen, the amorphous alloy or the nano-crystalline alloy may be an amorphous alloy powder or a nano-crystalline alloy powder. The amorphous alloy powder or nano-crystalline alloy powder may be by an atomizing method, the atomizing method including: preparing a melt in which three or more metal elements are melted; and injecting gas into the melt.

In the method of manufacturing the nanostructured film comprising nitrogen, the amorphous alloy or the nano-crystalline alloy may be a plurality of amorphous alloy ribbons or a plurality of nano-crystalline alloy ribbons. The amorphous alloy ribbon or the nano-crystalline alloy ribbon may be formed by a melt spinning method, the melt spinning method including: preparing a melt in which three or more metal elements are melted; and injecting the melt into a rotating roll.

In the method of manufacturing the nanostructured film comprising nitrogen, the amorphous alloy or the nano-crystalline alloy may be an amorphous alloy casting material or a nano-crystalline alloy casting material. The amorphous casting material or the nano-crystalline casting material may be formed by a copper mold casting method, the copper mold casting method including: preparing a melt in which three or more metal elements are melted; and injecting the melt into a copper mold by using pressure difference between outside and inside of the copper mold.

A method of manufacturing an amorphous alloy film according to another aspect of the present invention is provided. The method of manufacturing the amorphous alloy film includes: forming an amorphous alloy film on a substrate by unreactive sputtering an alloy target under Ar atmosphere in a sputtering apparatus, wherein a vein structure is observed at a fracture surface of the amorphous alloy film and a crystalline peak does not appear in X-ray diffraction analysis, wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy, wherein the alloy target has a microstructure in which crystal grains having an average size in the range of 0.1 μm through 5 μm are uniformly distributed, wherein the amorphous alloy or nano-crystalline alloy has 5 through 20 atomic % of Al, 15 through 40 atomic % of one or more selected from Cu and Ni, and a balance of Zr.

In the method of manufacturing an amorphous alloy film, the amorphous alloy film may have 5 through 20 atomic % of Al, 15 through 40 atomic % of one or more selected from Cu and Ni, and a balance of Zr.

A method of manufacturing an amorphous alloy film according to another aspect of the present invention is provided. The method of manufacturing the amorphous alloy film includes: forming an amorphous alloy film on a substrate by unreactive sputtering an alloy target under Ar atmosphere in a sputtering apparatus, wherein a vein structure is observed at a fracture surface of the amorphous alloy film and a crystalline peak does not appear in X-ray diffraction analysis, wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy, wherein the alloy target has a microstructure in which crystal grains having an average size in the range of 0.1 μm through 5 μm are uniformly distributed, wherein the amorphous alloy or nano-crystalline alloy has 5 through 20 atomic % of Al, 15 through 40 atomic % of one or more selected from Cu and Ni, more than 0 through 8 atomic % of one or more selected from Cr, Mo, Si, Nb, Co, Sn, In, Bi, Zn, V, Hf, Ag, Ti, and Fe, and a balance of Zr.

In the method of manufacturing an amorphous alloy film, the amorphous alloy film may have 5 through 20 atomic % of Al, 15 through 40 atomic % of one or more selected from Cu and Ni, more than 0 through 8 atomic % of one or more selected from Cr, Mo, Si, Nb, Co, Sn, In, Bi, Zn, V, Hf, Ag, Ti, and Fe, and a balance of Zr.

In the method of manufacturing an amorphous alloy film, the amorphous alloy or the nano-crystalline alloy may be an amorphous alloy powder or a nano-crystalline alloy powder. The amorphous alloy powder or nano-crystalline alloy powder may be formed by an atomizing method, the atomizing method including: preparing a melt in which three or more metal elements are melted; and injecting gas into the melt.

In the method of manufacturing an amorphous alloy film, the amorphous alloy or the nano-crystalline alloy may be a plurality of amorphous alloy ribbons or a plurality of nano-crystalline alloy ribbons. The amorphous alloy ribbon or the nano-crystalline alloy ribbon may be formed by a melt spinning method, the melt spinning method including: preparing a melt in which three or more metal elements are melted; and injecting the melt into a rotating roll.

In the method of manufacturing an amorphous alloy film, the amorphous alloy or the nano-crystalline alloy may be an amorphous alloy casting material or a nano-crystalline alloy casting material. The amorphous casting material or the nano-crystalline casting material may be formed by a copper mold casting method, the copper mold casting method including: preparing a melt in which three or more metal elements are melted; and injecting the melt into a copper mold by using pressure difference between outside and inside of the copper mold.

### Advantageous Effects

According to the embodiments of the present invention, a nanostructured film has significantly improved friction properties with high hardness and adhesion compared with the conventional film. Accordingly, when the nanostructured film is applied to various components used in frictional environments, the energy wasted by the friction can be reduced and the durability of the machine components can be increased. However, the scope of the present invention is not limited thereto.

### BRIEF DESCRIPTION OF THE DRAWINGS

FIG. 1 shows a surface of an alloy target used for manufacturing a nanostructured composite thin film after indentation test, according to an embodiment of the present invention.

FIG. 2 shows a surface of an alloy target of a comparative example after indentation test.

FIG. 3 is a schematic diagram showing a sputtering apparatus used for manufacturing a nanostructured composite thin film, according to an embodiment of the present invention.

FIG. 4 and FIG. 5 show X-ray diffraction analysis results for an amorphous alloy thin film, according to an embodiment of the present invention.

FIG. 6 shows cross-sections of an amorphous alloy thin film with low magnification and high magnification, according to an embodiment of the present invention.

FIG. 7 shows GEOES analysis results for an amorphous alloy thin film, according to an embodiment of the present invention.

FIG. 8 shows X-ray diffraction analysis results for a nanostructured composite thin film, according to an embodiment of the present invention.

FIG. 9 shows XPS analysis results for a nanostructured composite thin film, according to an embodiment of the present invention.

FIG. 10 shows roughness measurement results for a nanostructured composite thin film, according to an embodiment of the present invention.

FIG. 11 shows hardness and modulus of elasticity measurement results for a nanostructured composite thin film, according to an embodiment of the present invention.

FIG. 12 shows a high resolution transmission electron microscopy analysis results for an amorphous alloy thin film and a nanostructured composite thin film, according to an embodiment of the present invention.

FIG. 13 shows component distribution analysis results for a nanostructured composite thin film, according to an embodiment of the present invention.

FIG. 14 shows observation results for the surface of the nanostructured composite thin film after the scratch test, according to an embodiment of the present invention.

FIG. 15 shows observation results for the surface of the nanostructured composite thin film after the heat resistance test, according to an embodiment of the present invention.

FIG. 16 shows X-ray diffraction analysis results for a nanostructured composite thin film after the heat resistance test, according to an embodiment of the present invention.

FIG. 17 shows frictional lubrication test results for a nanostructured composite thin film with respect to the presence of a buffer layer, according to an embodiment of the present invention.

FIG. 18 and FIG. 19 show friction coefficients of a nanostructured composite thin film, according to an embodiment of the present invention.

FIG. 20 and FIG. 21 show frictional lubrication test results for a nanostructured composite thin film, according to an embodiment of the present invention.

### MODE OF INVENTION

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

In the specification and claims, the nanostructured film or amorphous alloy film may applied to both thin films and thick films according to the thickness of the layer.

Meanwhile, in the specification and claims, the nanostructured film had fine crystal grains having a crystal grain size, for example in the range of 5 nm through 30 nm, for example in the range of 5 nm through 10 nm. The nanostructured film may be a layer having a structure in which a nitride phase of metal and at least one metallic phase are mixed. The nanostructured film may be referred as, for example, a nanostructured composite thin film. Herein, the nitride phase of the metal may have at least one of Zr and Al as a component of the nitride. Furthermore, the nitride phase of the metal may have at least one of Cr, Mo, Si, Nb, Hf, Ti, V, and Fe as a component of the nitride.

Herein, the nanostructured composite thin film has a crystal structure of Zr nitride. Other metal elements, such as Al, may be dissolved in the Zr nitride as a form of nitride. Herein, the Zr nitride may have ZrN or Zr2N.

For example, Al may be dissolved ZrN by replacement of some of Zr in the crystal lattice of ZrN. Herein, the nitride having Zr and Al may be referred as a solid solution of ZrN and AlN.

Meanwhile, the metallic phase may have a metal element having lower nitrate formation ability than the metal element in the nitride. For example, the metallic phase may have one or more selected from Co, Sn, In, Bi, Zn, and Ag.

In the nanostructured composite thin film, the nitride phase of the metal has a nano-crystalline structure formed by crystal grains of several nanometer size through tens nanometer size. However, the metallic phase may be distributed in the nano crystal grain. For example, the metallic phase is distributed with a unit composed of several atoms, and thus does not form as a predetermined crystal structure. However, the metallic phase is distributed not in certain concentrated regions, but uniformly in the entire of the thin film.

The nanostructured composite thin film according to the embodiment of the present invention may be formed by sputtering with an alloy target. Herein, the alloy target may have a crystalline structure, and thus is referred as a crystalline alloy target.

Herein, the crystalline alloy target used for manufacturing the nanostructured composite thin film according to the present invention is an alloy having three or more elements with amorphous forming ability. The average crystal grain size of the alloy is equal to or less than 5 μm, for example in the range of 0.1 μm through 5 μm, for example in the range of 0.1 μm through 1 μm, for example in the range of 0.1 μm through 0.5 μm, for example in the range of 0.3 μm through 0.5 μm.

Herein, the amorphous forming ability is a relative criterion showing a degree of amorphization of an alloy having a predetermined composition with respect to a certain cooling rate. Generally, when an amorphous alloy is formed by a casting method, a cooling rate should be higher than a predetermined level. When a casting method with low cooling rate, for example copper mold casting method, is used, the composition range of forming an amorphous material decreases. A rapid solidification process, such as a melt spinning in which melted alloy is dropped on a rotating copper roll to form a ribbon or a wire rod, has a cooling rate in the range of 10⁴ K/sec through 106 K/sec, thereby increasing the composition range of forming an amorphous material. Therefore, the evaluation for the amorphous forming ability with respect to the composition range is generally related to a relative value according to the cooling rate of the given rapid solidifying process.

Since the amorphous forming ability is dependent of the alloy composition and the cooling rate, and the cooling rate is inversely proportional to a cast thickness [(cooling rate)∝(cast thickness)⁻²], the amorphous forming ability can be relatively quantified by evaluating a critical thickness of a casting material for obtaining an amorphous structure during casting. For example, in the copper mold casting method, the amorphous forming ability can be represented by a critical casting thickness (or diameter for a rod) of casting material for obtaining an amorphous structure. For example, when a ribbon is formed by the melt spinning method, the amorphous forming ability can be represented by a critical thickness of the ribbon for obtaining an amorphous structure.

In the specification and claims, the alloy having the amorphous forming ability is an alloy for forming an amorphous ribbon with a casting thickness in the range of 20 μm through 100 μm when a melt of the alloy is casted with a cooling rate in the range of 10⁴ K/sec through 10⁶ K/sec.

The crystalline alloy target used for a target for manufacturing a nanostructured composite thin film according to the present invention is realized by heating an amorphous alloy or nano-crystalline alloy composed of three or more metal elements having the amorphous forming ability described above at a temperature in the range of equal to or more than the crystallization starting temperature of the amorphous alloy or nano-crystalline alloy through less than the melting temperature of the amorphous alloy or nano-crystalline alloy.

Herein, in the specification and claims, the amorphous alloy does not have substantially a certain crystal structure. The X-ray diffraction pattern of the amorphous alloy does not show an obvious crystal peal (sharp peak) in a predetermined Bragg angle, but a broad peak in the broad range of angles. In addition, the nano-crystalline alloy may have an average size of the crystal grain less than 100 nm.

For the amorphous alloy, crystallization occurs during heating to generate a crystal grain growth. For the nano-crystalline alloy, the growth of the nano-crystal occurs. Herein, by controlling heating conditions, the average size of the crystal grains can be controlled within the above described range.

Herein, in the specification and claims, the crystallization starting temperature is a temperature when the crystallization of the amorphous alloy begins, and has a predetermined value according to the predetermined alloy composition. Accordingly, the crystallization starting temperature of the nano-crystalline alloy is a temperature when the crystallization of the amorphous alloy having the same composition as the nano-crystalline alloy begins.

The crystalline alloy target used for a target for manufacturing a nanostructured composite thin film according to the present invention may include, for example, at least one selected from Zr, Al, Cu and Ni. For example, The crystalline alloy target may include a ternary alloy having Zr, Al, and Cu, a ternary alloy having Zr, Al, and Ni, or a quaternary alloy having Zr, Al, Cu and Ni.

Herein, the alloy may have 5 atomic % through 20 atomic % of Al, 15 atomic % through 40 atomic % of one or more selected from Cu and Ni, and a balance of Zr.

As another example, the crystalline alloy target may have 5 atomic % through 20 atomic % of Al, 15 atomic % through 40 atomic % of one or more selected from Cu and Ni, more than 0 atomic % through 8 atomic % of one or more selected from Cr, Mo, Si, Nb, Co, Sn, In, Bi, Zn, V, Hf, Ag, Ti and Fe, and a balance of Zr.

The crystalline alloy target has much better thermal stability than an amorphous alloy having the same composition. That is, for the amorphous alloy, localized crystallization is generated by thermal energy transmitted from outside due to thermal instability, thereby locally forming nano-crystalline. The localized crystallization makes the amorphous alloy weak due to structure relaxation of the amorphous alloy, thereby the fracture toughness thereof is reduced.

However, for the crystalline alloy of the present invention, since the crystal grain size is controlled by the crystallization and/or crystal grain growth of the amorphous alloy or the nano-crystalline alloy, the change of the microstructure is not significantly changed when heat is added from the outside. Accordingly, the fracture due to thermal and mechanical instability of the conventional amorphous alloy or nano-crystalline alloy does not occur.

Ions accelerated by plasma during the process continuously collide to the sputtering target, and thus the temperature of the sputtering target consequently increases during the process. When the sputtering target is made of amorphous materials, the localized crystallization on the target surface may be generated due to temperature increase during the sputtering process. The localized crystallization increases brittleness of the target, and thus the target may be easily broken during the sputtering process.

However, the crystalline alloy according to the present invention has a microstructure in which crystal grains are controlled to be uniformly distributed with a predetermined range of sizes by the annealing process, thereby increasing thermal stability and mechanical stability. Accordingly, local changes in microstructures do not occur even when the temperature increases, and thus the above described mechanical instability does not occur. Accordingly, the crystalline alloy target according to the present invention can be used for manufacturing the amorphous thin film or the nano composite thin film using the sputtering method.

Hereinafter, a exemplary method of manufacturing an alloy target for sputtering using the crystalline alloy of the present invention will be described.

The alloy target for sputtering composed of the crystalline alloy of the present invention may be formed by casting the above described amorphous alloy or nano-crystalline alloy with similar sizes and shape to a real sputtering target. The amorphous alloy or nano-crystalline alloy is annealed to generate crystallization or grow crystal grains, thereby forming the crystalline alloy target.

In another method, a plurality of the above described amorphous alloy or the nano-crystalline alloy are prepared and combined each other by thermal pressing process, thereby forming the crystalline alloy target. During the thermal pressing process, the amorphous alloy or the nano-crystalline alloy may be elastically deformed.

Herein, the annealing process or the thermal pressing process are performed at a temperature in the range of equal to or more than the crystallization starting temperature of the amorphous alloy or the nano-crystalline alloy through less than the melting temperature of the amorphous alloy or the nano-crystalline alloy. The crystallization starting temperature is a temperature in which the phase of the alloy having a predetermined composition ratio is changed from an amorphous state to a crystalline state.

For example, the plurality of the amorphous alloy or the nano-crystalline alloy may be an amorphous alloy powder or a nano-crystalline alloy powder. The agglomerates of alloy powders are sintered under pressure in a sintering mold, thereby manufacturing a target having similar shape and size to the real target. In this case, the sintering process under pressure is performed at a temperature in the range of equal to or more than the crystallization starting temperature of the amorphous alloy through less than the melting temperature of the amorphous alloy. During the heating process, the agglomerates of the amorphous alloy powders or the nano-crystalline alloy powders are combined each other by mutual diffusion process thereof, thereby generating the crystallization and/or the crystal grain growth. Herein, during the crystallization and/or the crystal grain growth, in order that the size of the crystal grains is in a predetermined size range, the time and/or temperature are controlled. Accordingly, the crystallized or crystal grain grown alloy may have a crystal grain size equal to or less than 5 μm, for example in the range of 0.1 μm through 5 μm, for example in the range of 0.1 μm through 1 μm, for example in the range of 0.1 μm through 0.5 μm, for example in the range of 0.3 μm through 0.5 μm.

Herein, the amorphous alloy powder or the nano-crystalline alloy powder may be manufactured by an atomizing method. Specifically, the above described elements having the amorphous forming ability are melted. Then the melt is injected and inert gas such as argon gas is simultaneously sprayed to the injected melt, thereby rapidly cooling the melt to form alloy powders.

As another example, the plurality of the amorphous alloys or the nano-crystalline alloy may be amorphous alloy ribbons or nano-crystalline alloy ribbons. The plurality of ribbons are stacked and thermal pressed at a temperature in the range of equal to or more than the crystallization starting temperature of the alloy ribbons through less than the melting temperature of the alloy ribbons, thereby forming the target. During the thermal pressing process, the stacks of the amorphous alloy ribbons or the nano-crystalline alloy ribbons are combined each other by mutual diffusion process thereof, thereby generating the crystallization and/or the crystal grain growth. Herein, during the crystallization and/or the crystal grain growth, interfaces between the stacks may be disappeared due to the mutual diffusion.

Herein, the amorphous alloy ribbon or nano-crystalline alloy ribbon may be manufactured by a rapid solidification process such as a melt spinning method. Specifically, the above described elements having the amorphous forming ability are melted. Then, the melt is injected onto a surface of a rotating roll with high rotational speed thereby rapidly cooling the melt to form amorphous alloy ribbons or nano-crystalline alloy ribbons.

As another example, the plurality of the amorphous alloys or the nano-crystalline alloy may be amorphous alloy casting materials or nano-crystalline alloy casting materials. Herein, the amorphous alloy casting material or the nano-crystalline alloy casting material has a cylindrical shape or a plate shape. During the thermal pressing process, the stacks of the amorphous alloy casting materials or the nano-crystalline alloy casting materials are combined each other by mutual diffusion process of the individual alloy casting material, thereby generating the crystallization and/or the crystal grain growth. Herein, interfaces between the alloy casting materials may be disappeared due to the mutual diffusion.

Herein, the amorphous alloy casting material or nano-crystalline alloy casting material may be manufactured by a suction method or a pressing method in which the melt is inserted into a mold having high cooling ability, such as copper, by using pressure difference between the inside and outside of the mold. For example, in the copper mold casting method, the melt in which the above described elements having the amorphous forming ability are melted is prepared. Then, the melt is pressed or sucked to insert with a high rate through a nozzle into a copper mold. The melt is rapidly cooled to form an amorphous alloy casting material or a nano-crystalline alloy casting material having a predetermined shape.

The result alloy made from the alloy ribbon or the alloy casting material is controlled to have a crystal grain size in the above described range like the case of the alloy powder.

When a thin film is formed on a matrix by an unreactive sputtering with such a crystalline alloy target, the thin film may be an amorphous alloy thin film. Herein, the unreactive sputtering is a sputtering with an inert gas, for example Ar, without any reactive gas reacting with composition materials of the nano-crystalline alloy target.

The crystalline alloy target has the amorphous forming ability. Accordingly, for a process like sputtering in which solid phases are formed with high cooling rate, an amorphous alloy may be formed. Herein, the amorphous alloy thin film has a similar composition ratio to the nano-crystalline alloy target used in the sputtering.

In addition, when a thin film is formed on a matrix by a reactive sputtering with such a crystalline alloy target, the thin film may have a nanostructured composite thin film. For example, when the reactive gas, for example, nitrogen gas (N2) or any gas having nitrogen (N), for example NH3, are injected into a sputtering chamber and sputtering is performed, Zr highly reactive to the nitrogen in the alloy reacts with the nitrogen to form a Zr nitride, for example ZrN or Zr2N. In addition, Al may form an Al nitride, for example AlN. Other elements may be dissolved in the Zr nitride or may be presence as a metallic phase.

Herein, the thin film has crystal grains with nano level size, for example in the range of 5 mm through 30 nm, for example in the range of 5 mm through 10 nm.

The nanostructured composite thin film according to the embodiments of the present invention has high hardness and low difference in the modulus of elasticity compared with the metal matrix because the Zr nitride having high hardness the metal alloy having relatively low modulus of elasticity are mixed and the crystal grains has nano level size. In particular, the low friction properties is greatly improved compared with conventional case, which will be described later.

In order to improve the properties of the matrix on which the nanostructured composite thin film is formed, under a lower portion of the nanostructured composite thin film, that is, between the matrix and the nanostructured composite thin film, a buffer layer may be further formed. Herein, the buffer layer may be, for example, an adhesion layer to increase adhesive force of the nanostructured composite thin film to the matrix. As another example, the buffer layer may be a stress relaxation layer in which stress between the matrix and the nanostructured composite thin film is relaxed. As another example, the buffer layer may be a corrosion resistance layer so as to increase corrosion resistance ability. However, the present invention is not limited thereto, and the buffer layer may have a layer inserted into the nanostructured composite thin film and the matrix with respect to the structure of the thin film.

The buffer layer may be an amorphous alloy thin film formed by using the above described crystalline alloy target. In particular, in the process of coating the matrix using the sputtering after the nano-crystalline alloy target is installed in the sputtering chamber, an amorphous alloy thin film with a predetermined thickness is formed on a upper portion of the matrix using the unreactive sputtering, and then a nitrogen gas is injected into the sputtering chamber to perform the sputtering, thereby forming the nanostructured composite thin film. In this case, the buffer layer and the nanostructured composite thin film are in-situ formed using the same nano-crystalline alloy target. However, the present invention is not limited thereto, and the amorphous alloy thin film of the buffer layer and the nanostructured composite thin film may be formed using different crystalline targets having different compositions, and may be formed separately formed in individual chambers.

As another example, the buffer layer may be a metal layer formed by using another target, for example a Ti layer using a Ti target. As another example, a dual layer in which a Ti layer and an amorphous alloy thin film layer are sequentially stacked from the surface of the metal matrix.

Herein, an interface between the buffer layer and the nanostructured composite thin film may have a boundary layer in which the nitrogen or elements of the buffer layer has a gradient composition. That is, the composition of the boundary layer is not drastically changed at the interface, but gradually changed to have a gradient composition.

Hereinafter, embodiments are provided in order to understand the present invention. However, since the embodiments are provided only for describing the present invention, the present invention is not limited thereto.

Manufacturing a Sputtering Target

Crystalline alloy targets for manufacturing nanostructured composite thin films are manufactured. Table 1 and Table 2 shows results properties and crack generation results of alloy casting materials (for cylinders with 2 mm diameter or plates with 0.5 mm thickness) having various amorphous of various composition after annealing 800° C. Note that the alloy target 2 and the comparative example 1 are annealed at 800° C. Herein, the alloy casting materials are cylinders with 2 mm diameter or plates with 0.5 mm thickness.

TABLE 1

| | | Shape | | | | | | |
|---|---|---|---|---|---|---|---|---|
| | | and | Composition (atomic %) | | | | | |
| | Chemical | thickness | | | | | | Cu + |
| Alloy target | composition | of cast | Zr | Al | M | Cu | Ni | Ni |
| Embodiment 1 | Zn_{63.9}Al₁₀Cu_{26.1} | Φ 2 mm | 63.9 | 10.0 | 0 | 26.1 | 0 | 26.1 |
| Embodiment 2 | Zr_{63.9}Al₁₀Cu_{26.1} | Φ 2 mm | 63.9 | 10.0 | 0 | 26.1 | 0 | 26.1 |
| Embodiment 3 | Zr_{63.9}Al₆Cu_{24.4} | Φ 5 mm | 69.6 | 6.0 | 0 | 24.4 | 0 | 24.4 |
| Embodiment 4 | Zr₇₀Al₈Ni₁₆Cu₆ | Φ 2 mm | 70 | 8.0 | 0 | 6.0 | 16 | 22.0 |
| Embodiment 5 | Zr_{66.85}Al₉Cu_{24.15} | Φ 2 mm | 66.85 | 9.0 | 0 | 24.15 | 0 | 24.15 |
| Embodiment 6 | Zr_{71.6}Al₁₀Ni_{1.85}Cu_{16.55} | Φ 0.5 mm | 71.6 | 10.0 | 0 | 16.55 | 1.85 | 18.4 |
| Embodiment 7 | Zr_{66.2}Al₁₀Cu_{23.8} | Φ 2 mm | 66.2 | 10.0 | 0 | 23.8 | 0 | 23.8 |
| Embodiment 8 | Zr₅₉Al₁₀Cu₃₁ | Φ 2 mm | 59 | 10.0 | 0 | 31.0 | 0 | 31.0 |
| Embodiment 9 | Zr_{49.8}Al₁₀Cu_{40.2} | Φ 2 mm | 49.8 | 10.0 | 0 | 40.2 | 0 | 40.2 |
| Embodiment | Zr₅₅Al₁₀Ni₅Cu₃₀ | Φ 2 mm | 55 | 10.0 | 0 | 30.0 | 5.0 | 35.0 |
| 10 | | | | | | | | |
| Embodiment | Zr_{50.7}Al_{12.3}Ni₆Cu₂₈ | Φ 5 mmt | 50.7 | 12.3 | 0 | 28.0 | 9.0 | 37.0 |
| 11 | | | | | | | | |
| Embodiment | Zr_{52.6}Al_{16.4}Cu₃₁ | Φ 5 mmt | 52.6 | 16.4 | 0 | 31.0 | 0 | 31.0 |
| 12 | | | | | | | | |
| Embodiment | Zr_{52.2}Al₂₀Cu_{27.8} | Φ 5 mmt | 52.2 | 20.0 | 0 | 27.8 | 0 | 27.8 |
| 13 | | | | | | | | |
| Embodiment | Zr_{64.6}Al_{7.1}Cr_{2.2}Cu_{26.1} | Φ 2 mm | 64.6 | 7.1 | Cr: | 26.1 | 0 | 26.1 |
| 14 | | | | | 2.2 | | | |
| Embodiment | Zr₆₃Al₈Mo_{1.5}Cu_{27.5} | Φ 2 mm | 63 | 8.0 | Mo: | 27.5 | 0 | 27.5 |
| 15 | | | | | 1.5 | | | |
| Embodiment | Zr_{70.5}Al₁₀Si₂Cu_{17.5} | Φ 0.5 mm | 70.5 | 10.0 | Si: | 17.5 | 0 | 17.5 |
| 16 | | | | | 2.0 | | | |
| Embodiment | Zr₅₅Al₁₀Ni₁₀Nb₅Cu₂₀ | Φ 2 mm | 55 | 10.0 | Nb: | 20.0 | 10.0 | 30.0 |
| 17 | | | | | 5.0 | | | |
| Embodiment | Zr_{67.3}Al₁₀S₁Cu_{21.7} | Φ 2 mm | 67.3 | 10.0 | Si: | 21.7 | 0 | 21.7 |
| 18 | | | | | 1.0 | | | |
| Embodiment | Zr_{62.5}Al₁₀Mo₅Cu_{22.5} | Φ 2 mm | 62.5 | 10.0 | Mo: | 22.5 | 0 | 22.5 |
| 19 | | | | | 5.0 | | | |
| Embodiment | Zr_{65.2}Al₁₀Sn_{1.2}Cu_{23.6} | Φ 2 mm | 65.2 | 10.0 | Sn: | 23.6 | 0 | 23.6 |
| 20 | | | | | 1.2 | | | |
| Embodiment | Zr_{64.7}Al₁₀In₁Cu_{24.3} | Φ 2 mm | 64.7 | 10.0 | In: | 24.3 | 0 | 24.3 |
| 21 | | | | | 1.0 | | | |
| Embodiment | Zr_{64.5}Al₁₀Bi₁Cu_{24.5} | Φ 2 mm | 64.5 | 10.0 | Bi: | 24.5 | 0 | 24.5 |
| 22 | | | | | 1.0 | | | |
| Embodiment | Zr_{63.9}Al₁₀Zn_{1.4}Cu_{24.7} | Φ 2 mm | 63.9 | 10.0 | Zn: | 24.7 | 0 | 24.7 |
| 23 | | | | | 1.4 | | | |
| Embodiment | Zr_{63.8}Al₁₀V_{1.5}Cu_{24.7} | Φ 2 mm | 63.8 | 10.0 | V: | 24.7 | 0 | 24.7 |
| 24 | | | | | 1.50 | | | |
| Embodiment | Zr_{62.9}Al₁₀Hf₁Cu_{26.1} | Φ 5 mmt | 62.9 | 10.0 | Hf: | 26.1 | 0 | 26.1 |
| 25 | | | | | 1.0 | | | |
| Embodiment | Zr_{61.6}Al₁₂Fe₈Cu_{18.4} | Φ 2 mm | 61.6 | 10.0 | Fe: | 18.4 | 0 | 18.4 |
| 26 | | | | | 8.0 | | | |
| Embodiment | Zr_{59.3}Al₁₀Ti_{5.7}Ni_{1.8}Cu_{23.2} | Φ 5 mmt | 59.3 | 10.0 | Ti: | 23.2 | 1.8 | 25.0 |
| 27 | | | | | 5.7 | | | |
| Embodiment | Zr_{59.9}Al₁₀Ti₅Ni₆Cu_{23.5} | Φ 5 mmt | 59.9 | 10.0 | Ti: | 23.5 | 1.6 | 25.1 |
| 28 | | | | | 5.0 | | | |
| Embodiment | Zr_{63.5}Al₁₀Ag₂Cu_{24.5} | Φ 5 mmt | 63.5 | 10.0 | Ag: | 24.5 | 0 | 24.5 |
| 29 | | | | | 2.0 | | | |
| Embodiment | Zr_{68.9}Al₆Co_{3.5}Cu_{21.6} | Φ 5 mmt | 68.9 | 6.0 | Co: | 21.6 | 0 | 21.6 |
| 30 | | | | | 3.5 | | | |
| Comparative | Zr₅₀Ni₁₉Ti₁₆Cu₁₅ | Φ 5 mmt | 50 | 0.0 | Ti: | 15 | 19 | 34.0 |
| Example 1 | | | | | 16.0 | | | |
| Comparative | Zr₅₀Ni₁₉Ti₁₆Cu₁₅ | Φ 5 mmt | 50 | 0.0 | Ti: | 15 | 19 | 34.0 |
| Example 2 | | | | | 16.0 | | | |
| Comparative | Zr₅₅Al₂₀Ni₁₀Ti₅Cu₁₀ | Φ 5 mmt | 55 | 20.0 | Ti: | 10.0 | 10.0 | 20.0 |
| Example 3 | | | | | 5.0 | | | |
| Comparative | Zr₅₅Al₁₉Co₁₉Cu₇ | Φ 5 mmt | 55 | 19.0 | Co: | 7.0 | 0 | 7.0 |
| Example 4 | | | | | 19.0 | | | |

TABLE 2

| | | | | Crystal | | | |
|---|---|---|---|---|---|---|---|
| | | | | Grain size | | Hardness after | |
| | Amorphous | | | (μm) | | annealing | |
| Alloy | Properties | | | Aver- | Maxi- | Hard- | |
| Target | Tg | Tx | Tm | age | mum | ness | Cracks |
| Embodiment 1 | 404 | 470 | 913 | 0.35 | 2.6 | 599 | X |
| Embodiment 2 | 404 | 470 | 913 | 0.13 | 1.15 | 710 | X |
| Embodiment 3 | 365 | 415 | 942 | 0.51 | 4.23 | 475 | X |
| Embodiment 4 | 375 | 466 | 878 | 0.58 | 2.86 | 562 | X |
| Embodiment 5 | 383 | 457 | 902 | 0.46 | 2.54 | 502 | X |
| Embodiment 6 | 367 | 400 | 881 | 0.45 | 2.78 | 494 | X |
| Embodiment 7 | 388 | 447 | 906 | 0.4 | 2.56 | 559 | X |
| Embodiment 8 | 410 | 471 | 870 | 0.38 | 3.21 | 665 | X |
| Embodiment 9 | 439 | 519 | 856 | 0.68 | 5.73 | 518 | X |
| Embodiment 10 | 425 | 488 | 842 | 0.58 | 3.69 | 610 | X |
| Embodiment 11 | 452 | 514 | 840 | 0.6 | 3.6 | 623 | X |
| Embodiment 12 | 449 | 499 | 862 | 0.42 | 2.27 | 605 | X |
| Embodiment 13 | 399 | 470 | 903 | 0.48 | 2.91 | 604 | X |
| Embodiment 14 | 384 | 452 | 893 | 0.49 | 4.99 | 564 | X |
| Embodiment 15 | 400 | 474 | 901 | 0.38 | 4.64 | 602 | X |
| Embodiment 16 | 396 | 463 | 904 | 0.45 | 2.47 | 604 | X |
| Embodiment 17 | 441 | 498 | 829 | 0.51 | 4.4 | 656 | X |
| Embodiment 18 | 396 | 463 | 903 | 0.37 | 3.24 | 570 | X |
| Embodiment 19 | 409 | 480 | 879 | 0.39 | 1.52 | 651 | X |
| Embodiment 20 | 404 | 463 | 906 | 0.42 | 3.36 | 576 | X |
| Embodiment 21 | 396 | 467 | 902 | 0.5 | 5.1 | 606 | X |
| Embodiment 22 | 400 | 462 | 907 | 0.56 | 4.17 | 612 | X |
| Embodiment 23 | 397 | 467 | 911 | 0.54 | 3.99 | 577 | X |
| Embodiment 24 | 399 | 455 | 889 | 0.42 | 2.73 | 584 | X |
| Embodiment 25 | 400 | 477 | 907 | 0.37 | 3.11 | 644 | X |
| Embodiment 26 | 410 | 477 | 869 | 0.43 | 2.44 | 607 | X |
| Embodiment 27 | 396 | 477 | 833 | 0.53 | 5.49 | 571 | X |
| Embodiment 28 | 397 | 475 | 856 | 0.58 | 4.50 | 587 | X |
| Embodiment 29 | 405 | 469 | 879 | 0.42 | 3.70 | 636 | X |
| Embodiment 30 | 371 | 423 | 898 | 0.50 | 4.91 | 542 | X |
| Comparative | 311 | 489 | 794 | 0.32 | 3.15 | 502 | ◯ |
| Example 1 | | | | | | | |
| Comparative | 311 | 489 | 794 | 4.69 | 53.94 | 594 | ◯ |
| Example 2 | | | | | | | |
| Comparative | 437 | 491 | 915 | 1.92 | 6.80 | 725 | ◯ |
| Example 3 | | | | | | | |
| Comparative | 484 | 536 | 949 | 0.18 | 0.65 | 773 | ◯ |
| Example 4 | | | | | | | |

In Table 2, Tg, Tx, and Tm are a glass transition temperature, a crystallization starting temperature, and a melting temperature (a solid state temperature), respectively. The size of crystal grains were measured by the crystal grain diameter measurement method of the metal of KS D0205. Meanwhile, In Table 1, “M” indicates one or more metals besides Zr, Al, Ni and Cu.

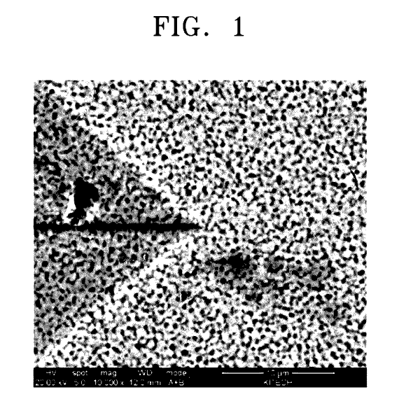

Referring to Table 1 and Table 2, the alloy targets 1 through 30 (embodiment 1 through 30) have crystalline structures, each of which crystal grains having sizes in the range of 0.1 μm through about 1 μm are uniformly distributed after annealing. When these crystalline structures are formed, cracks were not observed after the indentation test. As an example, FIG. 1 shows a microstructure of the alloy target 1 and the observation result of a surface after the indentation test in order to confirm the creation of cracks.

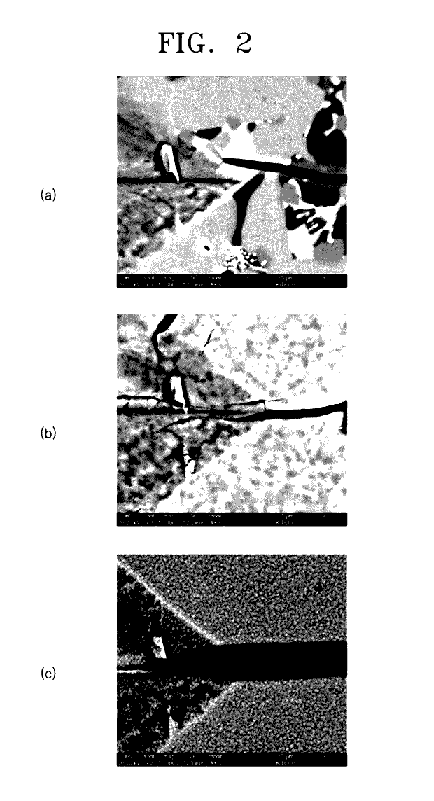

However, for the comparative example 1 in which the alloy does not have Al and for the comparative example 1 in which the annealing temperature is greater than the melting point, cracks were observed. Meanwhile, for the comparative example 3, when other metals besides Zr, Al, Cu, and Ni are added and Al is equal to or more than 20 atomic %, cracks were observed. FIG. 2a through FIG. 2c shows observation results of microstructures of comparative examples 2 through 4 after crack creation testing.

Manufacturing an Amorphous Alloy Thin Film

Thin films are formed using the sputtering method with the crystalline alloy targets manufactured by above described method. The sputtering is an unreactive sputtering (non-reactive sputtering) in which a metal thin film is formed under Ar atmosphere.

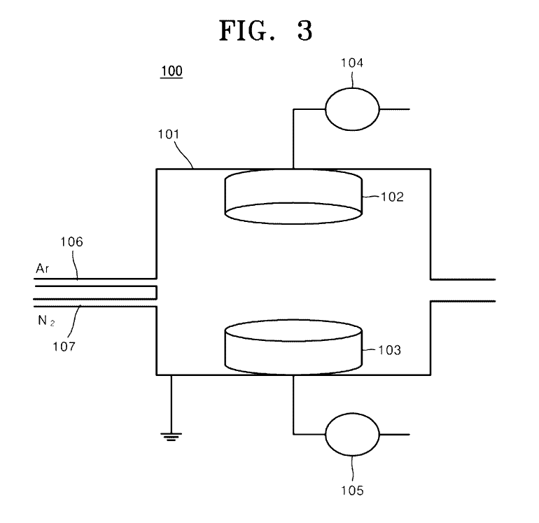

FIG. 3 shows a schematic diagram of magnetron sputtering used for the sputtering. The distance between a target 102 and a substrate holder 103 was controlled in the range of 50 mm through 80 mm. During processing, the chamber pressure was maintained at 5 mTorr and the total flow rate of gas injected was 36 sccm. When a thin film was formed by using an unreactive sputtering method, only Ar was injected through a gas line 106. When a thin film was formed by using a reactive sputtering method, 3 through 5 sccm of nitrogen gas was injected through a gas line 107 and Ar gas with the remaining flow rate was injected through a gas line 106.

Power in the range of 200 W through 450 W was applied to the target 102 through a power supply apparatus 104. A substrate 103 was not heated with any additional heating apparatus. The substrate holder 103 was connected to a pulse supply apparatus 105 applying direct current pulse to the substrate so as to plasma clean the surface of the substrate before the sputtering processing. The substrate was a High speed steel and a silicon wafer.

For evaluation of the obtained thin film, the hardness and the modulus of elasticity of the thin film was measured by a nano indentation method and the structure and the crystallization degree of the thin film was observed by an X-ray diffraction analysis. For the observation of microstructures, the cross section structure was analyzed by SEM (scanning electron microscopy) and the composition of the thin film was analyzed by EPMA (electron probe X-ray microanalysis) and GDOES (glow discharge optical emission spectrometry). The microstructure and the crystal grain size inside of the thin film were analyzed by high resolution transmission electron microscopy.

Table 3 shows serial numbers and corresponding compositions of the crystalline alloy targets used for manufacturing the above described thin films.

TABLE 3

Composition (atomic %)

| Target | Zr | Al | M | Cu |
|---|---|---|---|---|
| 1 | 63.9 | 10 | — | 26.1 |
| 5 | 66.85 | 9 | — | 24.15 |
| 14 | 64.6 | 7.1 | Cr: 2.2 | 26.1 |
| 15 | 63 | 8 | Mo: 1.5 | 27.5 |
| 16 | 70.5 | 10 | Si: 2 | 17.5 |
| 18 | 67.3 | 10 | Si: 1 | 21.7 |
| 19 | 62.5 | 10 | Mo: 5 | 22.5 |
| 23 | 63.9 | 10 | Zn: 1.4 | 24.7 |
| 31 | 64.4 | 12 | Co: 3 | 20.6 |
| 32 | 57.3 | 10 | Ni: 5 | 27.7 |
| 33 | 59.3 | 12.2 | Ag: 3.5 | 25 |
| 34 | 65.6 | 10 | Co: 3 | 21.4 |
| 35 | 56.3 | 9.3 | Fe: 5 | 29.4 |
| Comparative Example 4 | 70 | — | — | 30 |

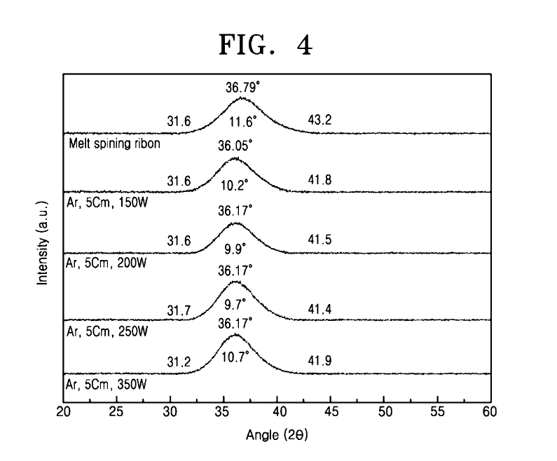

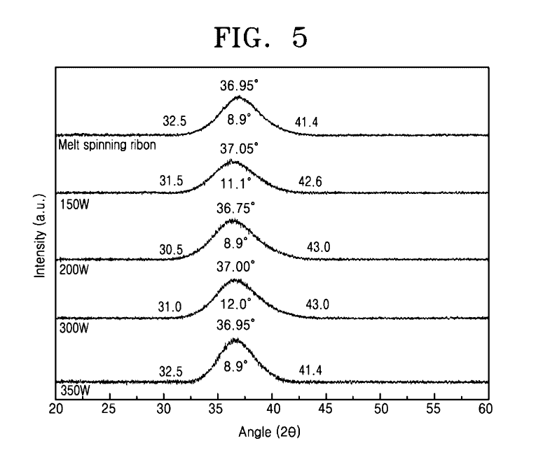

FIG. 4 and FIG. 5 show X-ray diffraction analysis results of crystal structures of thin films formed by the unreactive sputtering for the target 1 (Zr_{63.9}Al₁₀Cu_{26.1}) and the target 19 (Zr_{62.5}Al₁₀Mo₅Cu_{22.5}), respectively. During the sputtering process, the distance between the target and the substrate were maintained at 50 mm, and the power applied to the target was changed in the range of 150 W through 350 W. Meanwhile, the analysis results were compared with X-ray diffraction analysis results of ribbons formed by a rapid solidification process, a melt spinning process.

Referring to FIG. 4 and FIG. 5, all of the thin films formed by the unreactive sputtering using only Ar gas have amorphous structures. Herein, the X-ray diffraction analysis results of the thin films with respect to the sputtering power (that is, the power applied to the target), one of important process factors of the sputtering shows almost same characteristics for all conditions. That is, the position (2θ value) of the wide Bragg peak (diffuse Bragg peak), one of characteristics of the amorphous structure is almost same as that of the corresponding the parent material, the ribbon. That is, the thin films formed by the sputtering are amorphous thin films, and the positions of the Bragg peak are almost same as those of the corresponding composition ribbon within less than 1o. This result indicates that the composition of the crystalline alloy, the parent material, is almost congruently transferred to the thin film through the unreactive sputtering.

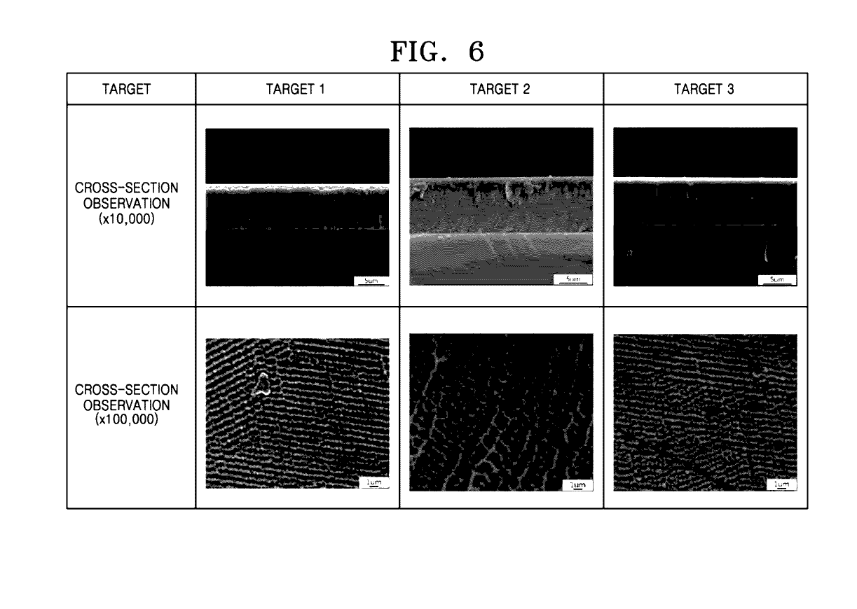

FIG. 6a through FIG. 6c are SEM photographs with various magnifications showing the cross-sectional structures of the thin films formed by the unreactive sputtering for the target 1 (Zr_{63.9}Al₁₀Cu_{26.1}), the target 31 (Zr_{64.4}Al₁₂Co₃Cu_{20.6}) and the target 19 (Zr_{62.5}Al₁₀Mo₅Cu_{22.5}).

Referring to FIG. 6a through FIG. 6c, the cross sections are featureless under 10,000 magnification, but vein structures shown in an amorphous structure are observed under 100,000 magnification. The vein structure is usually formed when an amorphous structure is significantly deformed when broken. The presence of the vein structure indicates high mechanical properties of the amorphous thin film. For this reason, the amorphous layer formed by the unreactive sputtering has a excellent characteristics as a buffer layer for the nanostructured composite thin film formed by the reactive sputtering and having high hardness.

Table 4 shows EPMA analysis results of thin films formed by the unreactive sputtering for the target 1 (Zr_{63.9}Al₁₀Cu_{26.1}), the target 31 (Zr_{64.4}Al₁₂Co₃Cu_{20.6}), the target 19 (Zr_{62.5}Al₁₀Mo₅Cu_{22.5}) and the target comparative example 4 (Zr₇₀Cu₃₀). The powers applied to the targets were 150 W and 200 W. The results shows that the difference between all thin films and the corresponding alloy targets are less than 1 atomic %. These results are found on the surfaces and inside of the thin films.

TABLE 4

| | | | Composition of thin film | | | | |
|---|---|---|---|---|---|---|---|
| Target | Composition | Power | Zr | Cu | Al | Mo | Co |
| Comparative Example 4 | Zr₇₀Cu₃₀ | 150 W | 72.45 | 27.55 | | | |
| Comparative Example 4 | Zr₇₀Cu₃₀ | 200 W | 73.12 | 26.88 | | | |
| 1 | Zr_{63.9}Al₁₀Cu_{26.1} | 150 W | 65.77 | 23.48 | 10.75 | | |
| 1 | Zr_{63.9}Al₁₀Cu_{26.1} | 200 W | 66.23 | 22.12 | 11.65 | | |
| 19 | Zr_{62.5}Al₁₀Mo₅Cu_{22.5} | 150 W | 62.31 | 21.01 | 10.78 | 5.90 | |
| 19 | Zr_{62.5}Al₁₀Mo₅Cu_{22.5} | 200 W | 62.45 | 20.62 | 10.83 | 6.10 | |
| 31 | Zr_{64.4}Al₁₂Co₃Cu_{20.6} | 150 W | 64.51 | 18.63 | 13.44 | — | 3.42 |
| 31 | Zr_{64.4}Al₁₂Co₃Cu_{20.6} | 200 W | 63.77 | 18.88 | 13.76 | — | 3.59 |

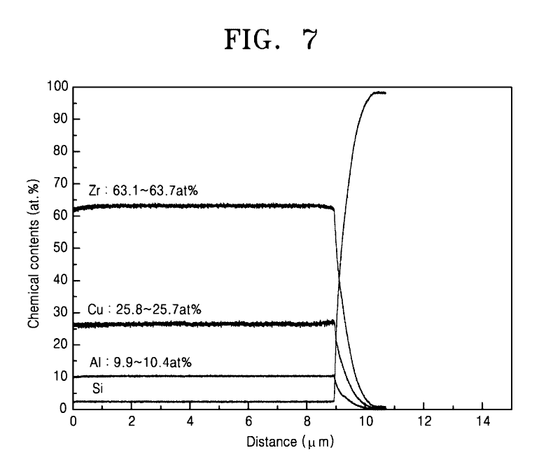

FIG. 7 shows GEOES analysis results of the amorphous alloy thin film for the target 19 (Zr_{62.5}Al₁₀Mo₅Cu_{22.5}) of Table 4. Referring to FIG. 7, all component elements are uniformly distributed inside of the thin film. According to the present invention, the composition of the thin film is almost same as that of the alloy target, because the composition of the target is almost uniformly transferred to the thin film.

Manufacturing a Nanostructured Composite Thin Film

Nanostructured composite thin films were formed using the crystalline alloy targets. The sputtering was the reactive sputtering by which the thin film having a nitride layer is formed under Ar and N2 mixed atmosphere.

Here, as process factors for the sputtering, plasma generating power, distance, the amount of nitrogen gas were changed. As an example, Table 4 shows thin film thickness and deposition rates when thin films are formed by 300 W power for the target 5 (Zr_{66.85}Al₉Cu_{24.15}), the target 15 (Zr₆₃Al₈Mo_{1.5}Cu_{27.5}) and the target 32 (Zr_{57.3}Al₁₀Ni₅Cu_{27.7}).

Referring to Table 5, almost same nitride properties are shown regardless of the distance and the flow rate of gas, and the thin films show gold color. Herein, the deposition rates were equal to or more than 0.05 μm/minute even at the 8 cm distance, and thus the deposition rate is very excellent.

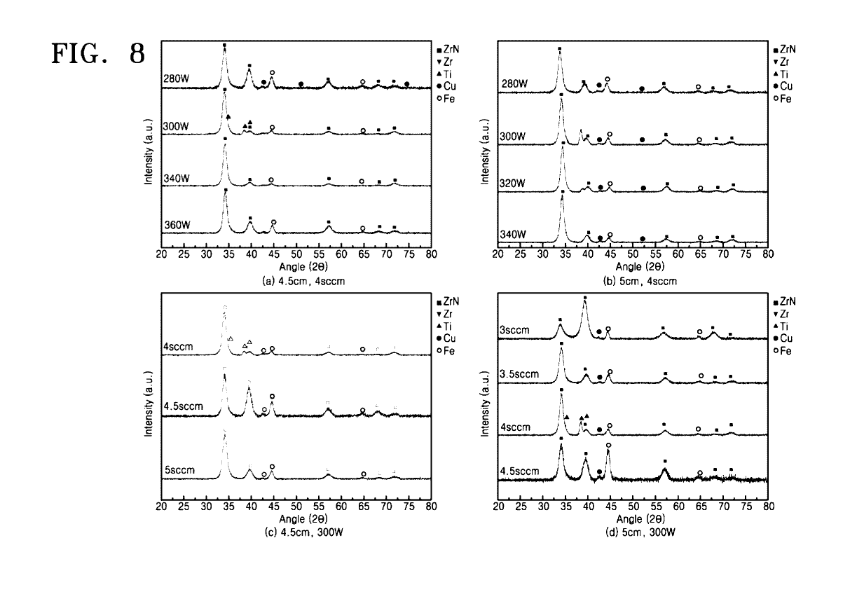

FIG. 8a through FIG. 8d show X-ray diffraction analysis results of the nanostructured composite thin film with respect to the thin film forming condition for the target 5 (Zr_{66.85}Al₉Cu_{24.15}). FIG. 8a shows analysis results when the target-specimen distance was 4.5 cm, the flow rate of nitrogen was 4.5 sccm, and the target power was changed to be 280 W, 300 W, 340 W, and 360 W. FIG. 8b shows analysis results with same conditions except for 5 cm of the target-specimen distance. FIG. 8c shows analysis results when the target-specimen distance was 4.5 cm, the target power was 300 W, the flow rate of nitrogen was changed to be 4 sccm, 4.5 sccm, and 5 sccm. FIG. 8d shows analysis results when the target-specimen distance was 5 cm, the target power was 300 W, the flow rate of nitrogen was changed to be 3 sccm, 3.5 sccm, 4 sccm, and 4.5 sccm.

From the X-ray diffraction analysis results, peak of Zr nitrides formed by nitride reaction was found each of the thin films. Herein, ZrN was found as the Zr nitrides. ZrN of the Zr nitrides shows the change in the preferred orientation according to the thin film forming condition. For example, referring to FIG. 8a through FIG. 8c, (111) preferred orientation was observed. Referring to FIG. 8d, (200) preferred orientation was observed under the conditions of 300 W of the target power and 3 sccm of the flow rate of nitrogen.

TABLE 5

| | | Target- | Nitrogen | Thin Film | Deposition |
|---|---|---|---|---|---|
| | Alloy | Specimen | Flow | Thickness | Rate |
| Target | Composition | Distance | Rate | (μm) | (μm/min) |
| 5 | Zr_{66.85}Al₉Cu_{24.15} | 5 cm | 3.5 sccm | 1.07 | 0.107 |
| 5 | Zr_{66.85}Al₉Cu_{24.15} | 5 cm | 4 sccm | 0.89 | 0.089 |
| 5 | Zr_{66.85}Al₉Cu_{24.15} | 6.5 cm | 3.5 sccm | 0.70 | 0.069 |
| 5 | Zr_{66.85}Al₉Cu_{24.15} | 6.5 cm | 4 sccm | 0.71 | 0.071 |
| 5 | Zr_{66.85}Al₉Cu_{24.15} | 8 cm | 3.5 sccm | 0.62 | 0.062 |
| 5 | Zr_{66.85}Al₉Cu_{24.15} | 8 cm | 4 sccm | 0.70 | 0.070 |
| 15 | Zr₆₃Al₈Mo_{1.5}Cu_{27.5} | 5 cm | 3.5 sccm | 0.81 | 0.081 |
| 15 | Zr₆₃Al₈Mo_{1.5}Cu_{27.5} | 5 cm | 4 sccm | 0.98 | 0.098 |
| 15 | Zr₆₃Al₈Mo_{1.5}Cu_{27.5} | 6.5 cm | 3.5 sccm | 0.60 | 0.060 |
| 15 | Zr₆₃Al₈Mo_{1.5}Cu_{27.5} | 6.5 cm | 4 sccm | 0.65 | 0.065 |
| 15 | Zr₆₃Al₈Mo_{1.5}Cu_{27.5} | 8 cm | 3.5 sccm | 0.56 | 0.056 |
| 15 | Zr₆₃Al₈Mo_{1.5}Cu_{27.5} | 8 cm | 4 sccm | 0.46 | 0.046 |
| 32 | Zr_{57.3}Al₁₀Ni₅Cu_{27.7} | 5 cm | 3.5 sccm | 1.17 | 0.117 |
| 32 | Zr_{57.3}Al₁₀Ni₅Cu_{27.7} | 5 cm | 4 sccm | 1.21 | 0.121 |
| 32 | Zr_{57.3}Al₁₀Ni₅Cu_{27.7} | 6.5 cm | 3.5 sccm | 0.71 | 0.071 |
| 32 | Zr_{57.3}Al₁₀Ni₅Cu_{27.7} | 6.5 cm | 4 sccm | 0.77 | 0.077 |
| 32 | Zr_{57.3}Al₁₀Ni₅Cu_{27.7} | 8 cm | 3.5 sccm | 0.58 | 0.058 |
| 32 | Zr_{57.3}Al₁₀Ni₅Cu_{27.7} | 8 cm | 4 sccm | 0.61 | 0.0610.061 |

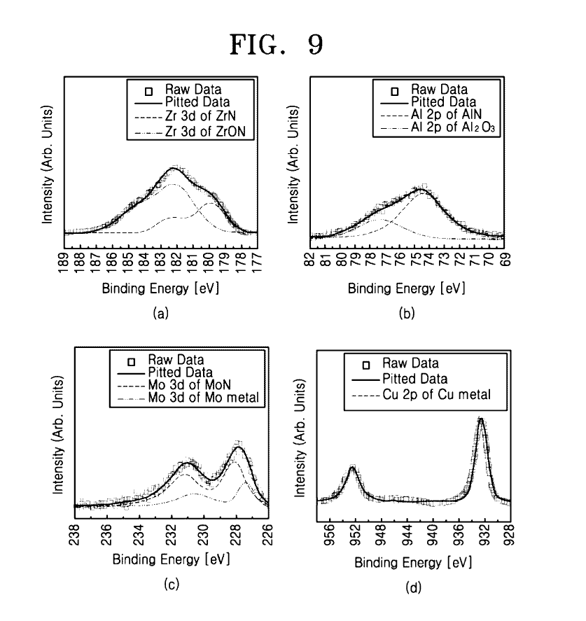

FIG. 9a through FIG. 9d show XPS (X-ray photoelectron spectroscopy) analysis results to verify the chemical bonding state of the thin film for the target 15 (Zr₆₃Al₈Mo_{1.5}Cu_{27.5}). FIG. 9a, FIG. 9b, FIG. 9c and FIG. 9d show analysis results of Zr, Al, Mo, and Cu, respectively.

Referring to FIG. 9a through FIG. 9c, it is observed that Zr and Al are present as ZrN and AlN, respectively, and some oxides thereof may be possible. This is formed by the combination of remaining oxygen inside of the sputtering apparatus with Zr and Al during the sputtering process. However, referring to 9d, it is observed that Cu is present as metal Cu state.

In the X-ray diffraction analysis results, the reason why the peaks of Al nitride phase and Mo nitride phase in the nitride phases are not observed may be the nitride of the metal elements is dissolved in Zr nitride, for example ZrN.

In addition, elements not to perform nitride, such as Cu, are present as a metallic state, and disposed in boundary region of nano crystal grains or has amorphous properties, thereby not being detected by X-ray diffraction analysis.

In the present embodiment, ZrN is formed as the Zr nitride, but the Zr nitride is not limited to ZrN in the present invention. Zr2N is formed as the Zr nitride according to the change of the process factors, for example, the decrease in the amount of nitrogen flow injected.

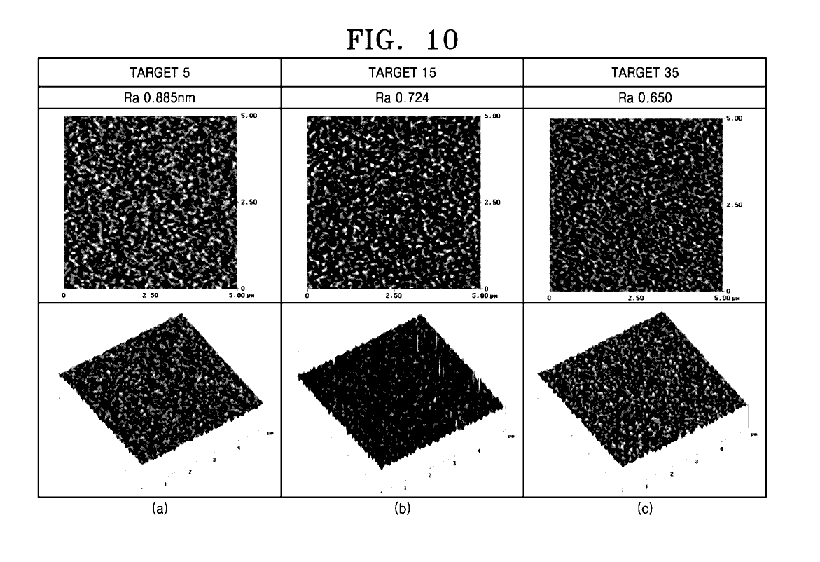

FIG. 10a through FIG. 10c are roughness results of a nanostructured composite thin film layer formed by the reactive sputtering for the target 5 (Zr_{66.85}Al₉Cu_{24.15}), the target 15 (Zr₆₃Al₈Mo_{1.5}Cu_{27.5}) and the target 34 (Zr_{65.6}Al₁₀Co₃Cu_{21.4}). The roughness results were obtained by AFM (atomic force microscopy).

Referring to FIG. 9a through FIG. 9c, the nanostructured composite thin films have very superior roughness values equal to or less than 1 nm of Ra, especially compared with 10 nm requirement by vehicle part manufactures.

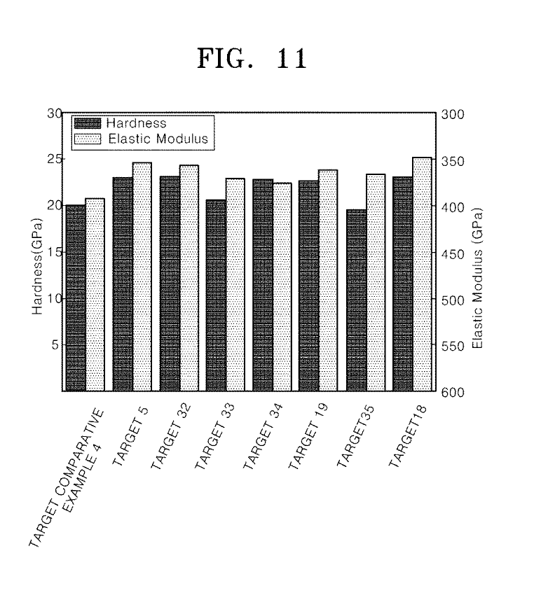

FIG. 11 shows hardness and modulus of elasticity of thin film obtained by a nano indentation method. The thin film is formed by reactive sputtering using nano-crystalline alloy targets with various compositions. In FIG. 11, the x-axis shows the composition of the crystalline alloy target used in the reactive sputtering. Referring to FIG. 10, all nanostructured composite thin films has high hardness values, for example, equal to or more than about 20 GPa. This value is close to that of high hardness ceramic material. In addition, all nanostructured composite thin films have the equal to or less than about 250 GPa of modulus of elasticity. This value is close to that of commercial metal material such as steel. Accordingly, when the nanostructured composite thin film according to the present invention is coated on a metal material such as steel, high hardness and high durability can be obtained compared with high hardness ceramic material.

FIG. 12a and FIG. 12b show high resolution transmission electron microscopy analysis results of thin films formed by unreactive sputtering and reactive sputtering for target 34 (Zr_{65.6}Al₁₀Co₃Cu_{21.4}).

Referring to FIG. 12a, in the thin film formed by the unreactive sputtering, halo pattern, amorphous phase characteristics, is observed in selected area diffraction pattern (upper right portion of FIG. 11a). The lattice array was not observed in the high magnification photographs.

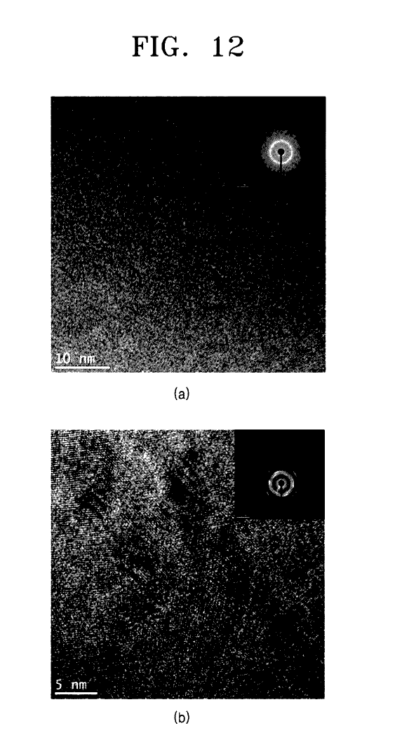

Meanwhile, referring to FIG. 12b, in the thin film formed by the reactive sputtering, atoms are directionally arranged, as shown in the high magnification photograph. By the investigation of the region in which atoms are uniformly arranged, crystal grains having 5 mm through 10 nm size can be observed. In addition, in the SAD pattern, ring patterns are shown, which indicates the presence of nano crystal structure. Referring to FIG. 13a through FIG. 13e, as cross-section EDS (energy dispersive spectroscopy) analysis results for the thin film of FIG. 12b, it is observed that elements forming the thin film are uniformly distributed.

Table 6 shows experimental results for the formation of the buffer layer in order to improve adhesive force of the nanostructured composite thin film. The buffer layer was amorphous alloy thin film and Ti layer. The amorphous alloy thin film and the nanostructured composite thin film are formed using the target 5 (Zr_{66.85}Al₉Cu_{24.15}). The Ti layer was formed using the Ti target. The substrate was high speed steel.

TABLE 6

| | | | | | | | Nano | |
|---|---|---|---|---|---|---|---|---|
| | | | | | | | structure | |
| | | | | | | Buffer | Composite | |
| | | Buffer | | | Critical | Layer | Thin film | Total |
| | | Layer | Coating | | Value | Thickness | Thickness | Thickness |
| # | Target | Type | Condition | Power | [N] | [μm] | [μm] | [μm] |
| 1 | 1 | Ti layer/ | 5 cm/ | 300 W | 50.0 | 0.55 | 2.00 | 2.55 |
| | | Amorphous | 4.5 sccm | | | | | |
| | | Alloy | | | | | | |
| | | Thin film | | | | | | |
| | | Dual layer | | | | | | |
| 2 | 5 | Ti layer/ | 5 cm/ | 340 W | 50.0 | 0.81 | 2.10 | 2.91 |
| | | Amorphous | 4.5 sccm | | | | | |
| | | Alloy | | | | | | |
| | | Thin film | | | | | | |
| | | Dual layer | | | | | | |
| 3 | 5 | Ti layer/ | 5 cm/ | 320 W | 28.4 | 0.74 | 2.62 | 3.36 |
| | | Amorphous | 4 sccm | | | | | |
| | | Alloy | | | | | | |
| | | Thin film | | | | | | |
| | | Dual layer | | | | | | |
| 4 | 5 | Amorphous | 5 cm/ | 300 W | 39.7 | 0.53 | 2.53 | 3.06 |
| | | Alloy | 4.5 sccm | | | | | |
| | | Thin film | | | | | | |
| 5 | 5 | Amorphous | 5 cm/ | 340 W | 28.0 | 0.51 | 3.26 | 3.77 |
| | | Alloy | 4.5 sccm | | | | | |
| | | Thin film | | | | | | |
| 6 | 5 | Amorphous | 5 cm/ | 320 W | 50.0 | 0.38 | 1.96 | 2.34 |
| | | Alloy | 4 sccm | | | | | |
| | | Thin film | | | | | | |
| 7 | 5 | Ti layer | 5 cm/ | 300 W | 33.2 | 0.40 | 2.88 | 3.28 |
| | | | 4.5 sccm | | | | | |
| 8 | 5 | Ti layer | 5 cm/ | 340 W | 21.4 | 0.39 | 2.37 | 2.76 |
| | | | 4.5 sccm | | | | | |
| 9 | 5 | Ti layer | 5cm/ | 320 W | 34.9 | 0.20 | 2.71 | 2.91 |
| | | | 4 sccm | | | | | |

Table 7

Prior to forming the nanostructured composite thin film by the reactive sputtering, the amorphous thin film layer was formed with the target or Ti layer was formed with Ti target using the unreactive sputtering. In other case, the Ti layer and the amorphous alloy thin film were sequentially formed to make a dual layered buffer layer. The adhesive force was found based on the comparison of critical values at which thin film was exfoliated using the scratch tester.

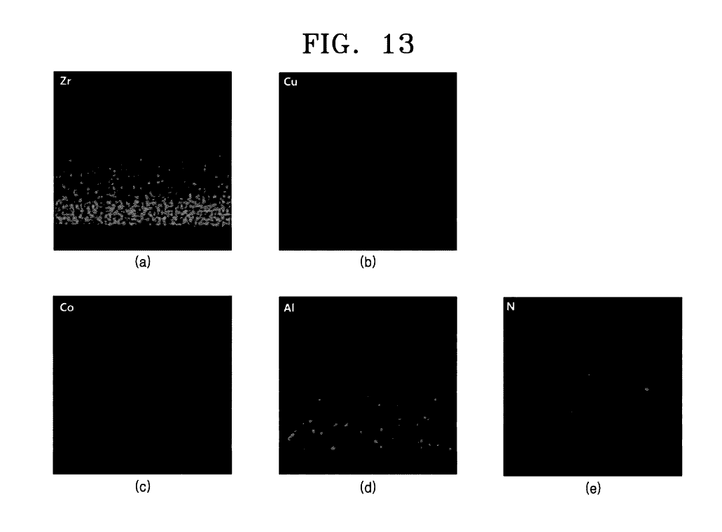

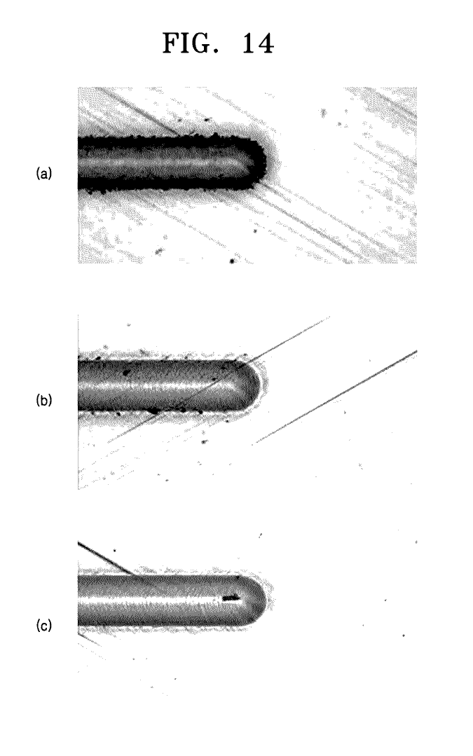

Referring to Table 6, all cases show high adhesive force equal to or more than 20N. In some cases, the adhesive force was equal to or more than 30 N required for some vehicle parts. In some cases, the adhesive force was equal to or more than 50 N capable to be used for mold. Referring to FIG. 14a through FIG. 14c, observation results of indentation marks after the scratch test of specimens (specimens 1, 2, and 6) having high adhesive force equal to or more than 50N are shown. Referring to FIG. 14a through FIG. 14c, serious exfoliations of the thin films near the indentation marks was not observed for all specimens, and thus all specimens have very high adhesion.

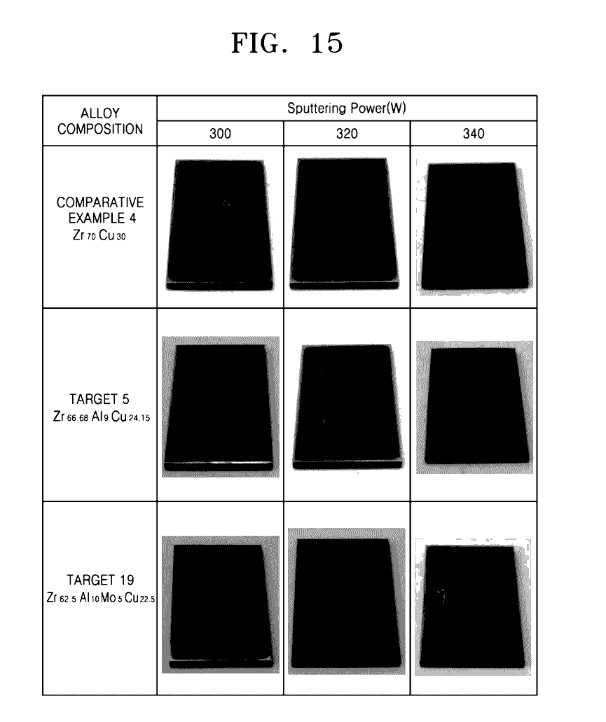

The nanostructured composite thin film according to the embodiments of the present invention has very high heat resistance properties. FIG. 15 shows the observation results of surfaces of the thin films for the target comparative example 4 (Zr₇₀Cu₃₀), the target 5 (Zr_{66.85}Al₉Cu_{24.15}) and the target 19 (Zr_{62.5}Al₁₀Mo₅Cu_{22.5}) after 3 hours annealing at 200, 300, 400, or 500° C. (evaluation conditions for vehicle parts). FIG. 16 shows X-ray diffraction results of the specimens. Herein, the specimens were made by high speed steel as a matrix used for abrasion test.

Referring to FIG. 15 and FIG. 16, the surfaces were not changed after 200° C. or 300° C. annealing. For the thin film formed by target comparative example 4 (Zr₇₀Cu₃₀), binary alloy, the surface thereof was damaged after 400° C., as shown in FIG. 15. These results are confirmed by the X-ray diffraction analysis. From the X-ray diffraction analysis results for specimens after annealing, as shown in FIG. 16, the thin film for the target comparative example 4 (Zr₇₀Cu₃₀) shows phase change after 400° C. annealing. This is due to the formation of oxides.

However, for the thin films for the target 5 (Zr_{66.85}Al₉Cu_{24.15}) and the target 19 (Zr_{62.5}Al₁₀Mo₅Cu_{22.5}), the crystal grain growth occurs and crystalline increases, thereby increasing the peak intensity of ZrN. However, the phase changes were not found.

Table 7 shows specimen conditions for the lubricative friction test of the nanostructured composite thin film.

TABLE 7

| Classification | Contents |
|---|---|
| Friction | Friction test apparatus: Round trip high temperature |
| Test | friction tester, |
| Condition | Load: 50, 100, 200, 300N, |
| | Round trip distance: 10 mm, |
| | Speed: 5 Hz (100 mm/sec.), |
| | Temperature: 90° C., 150° C. |
| Substrate | Material and shape: high speed steel, 34 × 20 × |
| | 1.5 mmt, |
| | Properties: quenching thermal treatment, |
| | hardness 700 ± 50 Hv, |
| | surface roughness: Ra 0.01~0.015 μm |
| Counter | Material and shape: SCM415, Φ 12 mm × 4 mmt, |
| Material | Properties: carburizing treatment, |
| | hardness 800 ± 50 Hv, |
| | surface roughness: Ra 0.095~0.105 μm |
| Oil | Oil type: 5W20 + MODTC, |
| | Oil injection amount: 1 drop(0.004 ± 0.001 g) or |
| | (4 ± 1 mg) |
| Coating | Buffer layer: 0.5 ± 0.1 μm, |
| Layer | nanostructured composite thin film: 2.5 ± 0.2 μm |
| Thickness | |

As a matrix for forming thin film, a high speed steel having 20 mm×34 mm size was quenched to obtain 700 Hv of surface hardness. It is polished to have equal to or less than 0.01 μm of surface roughness. Meanwhile, as a buffer layer, an amorphous alloy thin film, a Ti layer and a Ti layer/amorphous alloy thin film (dual layer) using the target 5 (Zr_{66.85}Al₉Cu_{24.15}) are formed, and then a nanostructured composite thin film is deposited thereon. The thickness of the thin film is equal to or more than 3 μm. During the lubricative friction test, the load was changes from 50 N to 300 N and the temperature was 90° C. and 150° C. The oil used for the lubricative friction test was a mixture of 5W20 base oil and MoDTC, a friction controller. The time for test was 10 minutes.

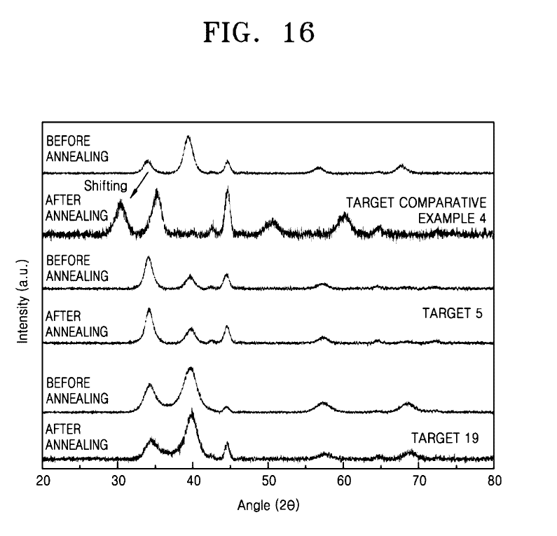

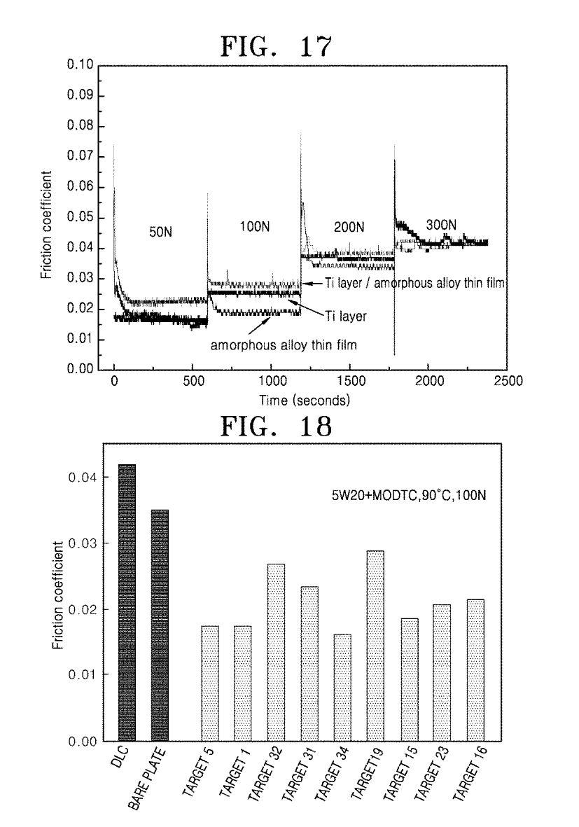

FIG. 17 shows results of observation of friction coefficients of the nanostructured composite thin film according to the type of the buffer layer. Referring to FIG. 17, the case that amorphous alloy thin film was used as the buffer layer shows the excellent friction coefficient. The Ti layer/amorphous alloy thin film (dual layer) buffer layer, the best adhesive force at the adhesive force test, shows low friction coefficient.

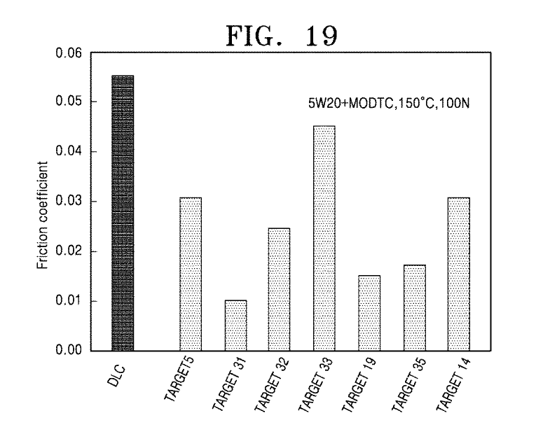

FIG. 18 and FIG. 19 shows friction coefficient results when 10 minute friction test was performed on the nanostructured composite thin film according to the present invention with 100 N of load and temperature of 90° C. and 150° C. In FIG. 18 and FIG. 19, x-axis shows the composition of the target used for manufacturing a nanostructured composite thin film. Meanwhile, as a comparative example, DLC coating layer, applied conventional vehicle part, and matrix without the thin film was evaluated together.

Referring to FIG. 18 and FIG. 19, the thin films for all compositions has significantly lower properties than that of DLC at 90° C. and 150° C.

In particular, for the thin film having Co and the thin film of Mo, the friction coefficient at 150° C. is lower than that at 90° C. The reason thereof is that the thin film reacts at high temperature lubricative environment to easily form lubricative material.

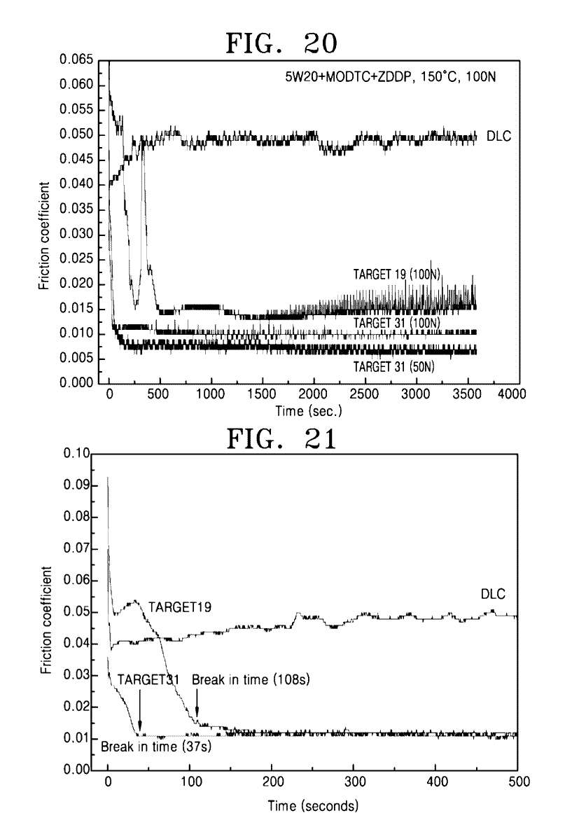

Based on the lubricative experiment results, the target 19 (Zr_{62.5}Al₁₀Mo₅Cu_{22.5}) and the target 31 (Zr_{64.4}Al₁₂Co₃Cu_{20.6}) having excellent properties is used to form the nanostructured composite thin film. The nanostructured composite thin film was tested for 1 hour. The results thereof are shown in FIG. 20. Herein, the comparative example was DLC coating layer.

Referring to FIG. 20, for DLC coating layer, the friction coefficient was not changed during abrasion test. However, for the present invention, the friction coefficient initially increased and then drastically decreased to maintain a stable friction coefficient. In particular, the nanostructured composite thin film for the target 31 (Zr_{64.4}Al₁₂Co₃Cu_{20.6}) having Co shows super lubricative property near 0.01. When solid phases contacts due to high load and high pressure, the temperature of contact region instantly increases to generate the reaction between solids or solid and oil. This reaction generates at boundary lubricative environment, and thus easy shear boundary films useful for lubricative properties are formed. Accordingly, they are advantageously affected to the friction properties.

The phenomenon in which initially high friction coefficient decreases due to the reaction during frictional abrasion is initial break in. Time for the break in is break in time. FIG. 21 shows the change of friction coefficient. For DLC, the friction coefficient is constant regardless of abrasion time. However, the nanostructured composite thin film according to the present invention initially showed a high friction coefficient and then the friction coefficient drastically decreased due to the reaction with lubricative phase.

The nanostructured composite thin film according to the present invention has high hardness and superior adhesion ability and low friction properties compared with the conventional case. The nanostructured composite thin film may be used for manufacturing a member having low friction properties for improving friction properties of various machine parts. For example, the nanostructured composite thin film can be applied to a tarpet, a piston ring, a piston pin, a cam cap, a journal metal bearing, an injector part, and the like as for vehicle engine parts so as to reduce friction and abrasion during engine driving. As another example, the nanostructured composite thin film can be applied to transmissions or gears in power train system, various molds, sliding bearings, cutting tools so as to reduce friction, thereby improving mechanical and chemical properties of parts.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

1. A method of manufacturing a nanostructured film comprising nitrogen, the method comprising:
forming a nanostructured film having nitrogen on a substrate by sputtering an alloy target with injection of a reactive gas having nitrogen or nitrogen gas (N2) or nitrogen (N) into a sputtering apparatus,
wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy,
wherein the alloy target has a microstructure in which crystal grains having an average size in the range of 0.1 μm through 5 μm are uniformly distributed,
wherein the amorphous alloy or nano-crystalline alloy has 5 atomic % through 20 atomic % of Al, 15 atomic % through 40 atomic % of one or more selected from Cu and Ni, and a balance of Zr.

2. A method of manufacturing a nanostructured film comprising nitrogen, the method comprising:
forming a nanostructured film having nitrogen on a substrate by sputtering an alloy target with injection of a reactive gas having nitrogen or nitrogen gas (N2) or nitrogen (N) into a sputtering apparatus,
wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy,
wherein the alloy target has a microstructure in which crystal grains having an average size in the range of 0.1 μm through 5 μm are uniformly distributed,
wherein the amorphous alloy or nano-crystalline alloy has 5 atomic % through 20 atomic % of Al, 15 atomic % through 40 atomic % of one or more selected from Cu and Ni, more than 0 atomic % through 8 atomic % of one or more selected from Cr, Mo, Si, Nb, Co, Sn, In, Bi, Zn, V, Hf, Ag, Ti, and Fe, and a balance of Zr.

3. The method of claim 1, further comprising:
forming a buffer layer on the substrate before forming the nanostructured film.

4. The method of claim 3, wherein the buffer layer comprises an amorphous alloy thin film or a Ti layer.

5. The method of claim 3, wherein the buffer layer has a dual layer structure in which a Ti layer and an amorphous alloy thin film are sequentially stacked on a matrix.

6. The method of claim 3, wherein an interface of the buffer layer and the nanostructured film has a boundary layer having a composition gradient of nitrogen or elements forming the buffer layer.

7. The method of claim 4, wherein the amorphous alloy thin film is formed by sputtering the alloy target.

8. The method of claim 1, wherein the amorphous alloy or the nano-crystalline alloy is an amorphous alloy powder or a nano-crystalline alloy powder.

9. The method of claim 8, wherein the amorphous alloy powder or nano-crystalline alloy powder is formed by an atomizing method, the atomizing method comprising:
preparing a melt in which three or more metal elements are melted; and
injecting gas into the melt.

10. The method of claim 1, wherein the amorphous alloy or the nano-crystalline alloy is a plurality of amorphous alloy ribbons or a plurality of nano-crystalline alloy ribbons.

11. The method of claim 10, wherein the amorphous alloy ribbon or the nano-crystalline alloy ribbon is formed by a melt spinning method, the melt spinning method comprising:
preparing a melt in which three or more metal elements are melted; and
injecting the melt into a rotating roll.

12. The method of claim 1, wherein the amorphous alloy or the nano-crystalline alloy is an amorphous alloy casting material or a nano-crystalline alloy casting material.

13. The method of claim 12, wherein the amorphous casting material or the nano-crystalline casting material is formed by a copper mold casting method, the copper mold casting method comprising:
preparing a melt in which three or more metal elements are melted; and
injecting the melt into a copper mold by using pressure difference between outside and inside of the copper mold.

14. A method of manufacturing an amorphous alloy film, the method comprising:
forming an amorphous alloy film on a substrate by unreactive sputtering an alloy target under Ar atmosphere in a sputtering apparatus,
wherein a vein structure is observed at a fracture surface of the amorphous alloy film and a crystalline peak does not appear in X-ray diffraction analysis,
wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy,
wherein the alloy target has a microstructure in which crystal grains having an average size in the range of 0.1 μm through 5 μm are uniformly distributed,
wherein the amorphous alloy or nano-crystalline alloy has 5 atomic % through 20 atomic % of Al, 15 atomic % through 40 atomic % of one or more selected from Cu and Ni, and a balance of Zr.

15. The method of claim 14, wherein the amorphous alloy film has 5 atomic % through 20 atomic % of Al, 15 atomic % through 40 atomic % of one or more selected from Cu and Ni, and a balance of Zr.

16. A method of manufacturing an amorphous alloy film, the method comprising:
forming an amorphous alloy film on a substrate by unreactive sputtering an alloy target under Ar atmosphere in a sputtering apparatus,
wherein a vein structure is observed at a fracture surface of the amorphous alloy film and a crystalline peak does not appear in X-ray diffraction analysis,
wherein the alloy target is formed by annealing an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy,
wherein the alloy target has a microstructure in which crystal grains having an average size in the range of 0.1 μm through 5 μm are uniformly distributed,
wherein the amorphous alloy or nano-crystalline alloy has 5 atomic % through 20 atomic % of Al, 15 atomic % through 40 atomic % of one or more selected from Cu and Ni, more than 0 atomic % but not more than 8 atomic % of one or more selected from Cr, Mo, Si, Nb, Co, Sn, In, Bi, Zn, V, Hf, Ag, Ti, and Fe, and a balance of Zr.

17. The method of claim 16, wherein the amorphous alloy film has 5 atomic % through 20 atomic % of Al, 15 atomic % through 40 atomic % of one or more selected from Cu and Ni, more than 0 atomic % through 8 atomic % of one or more selected from Cr, Mo, Si, Nb, Co, Sn, In, Bi, Zn, V, Hf, Ag, Ti, and Fe, and a balance of Zr.

18. The method of claim 14, wherein the amorphous alloy or the nano-crystalline alloy is an amorphous alloy powder or a nano-crystalline alloy powder.

19. The method of claim 18, wherein the amorphous alloy powder or nano-crystalline alloy powder is formed by an atomizing method, the atomizing method comprising:
preparing a melt in which three or more metal elements are melted; and
injecting gas into the melt.

20. The method of claim 14, wherein the amorphous alloy or the nano-crystalline alloy is a plurality of amorphous alloy ribbons or a plurality of nano-crystalline alloy ribbons.

21. The method of claim 20, wherein the amorphous alloy ribbon or the nano-crystalline alloy ribbon is formed by a melt spinning method, the melt spinning method comprising:
preparing a melt in which three or more metal elements are melted; and
injecting the melt into a rotating roll.

22. The method of claim 14, wherein the amorphous alloy or the nano-crystalline alloy is an amorphous alloy casting material or a nano-crystalline alloy casting material.

23. The method of claim 22, wherein the amorphous casting material or the nano-crystalline casting material is formed by a copper mold casting method, the copper mold casting method comprising:
preparing a melt in which three or more metal elements are melted; and
injecting the melt into a copper mold by using pressure difference between outside and inside of the copper mold.
